(19) United States
(12) Patent Application Publication
(10) Pub. No.: US 2011/0108889 A1
(43) Pub. Date: May 12, 2011

(54) SEMICONDUCTOR DEVICE WITH A 7F2 CELL STRUCTURE

(75) Inventors: SEAN XING, Shanghai (CN); Yongsheng Yang, Shanghai (CN); DeYuan Xiao, Shanghai (CN); Guo Qing Chen, Shanghai (CN)

(73) Assignee: Semiconductor Manufacturing International (Shanghai) Corporation, Shanghai (CN)

(21) Appl. No.: 12/938,178

(22) Filed: Nov. 2, 2010

(30) Foreign Application Priority Data
Nov. 10, 2009 (CN) 200910198600.2

(51) Int. Cl. H01L 27/108

(52) U.S. Cl. 257/208; 257/E27.084

(57) ABSTRACT

A semiconductor device with a 7F² cell structure. In one embodiment, a bit line pitch of about 2\sqrt{3}F and a word line pitch of about 2F may be configured for the semiconductor device. In one embodiment, each of the active areas of the semiconductor device may be rotated around a corresponding center region to be offset from a corresponding bit line region. A plurality of imaginary equal lateral triangles may be formed by connecting center regions located on adjacent bit line regions and by connecting adjacent center regions located on the same bit line region. In this manner, the active areas for the semiconductor device can be arranged in a close compact pile mode within the cell plane, thereby achieving better cell area utilization. The semiconductor device may be a dynamic random access memory (DRAM).

### CROSS-REFERENCES TO RELATED APPLICATIONS

This application claims priority to Chinese Application No. 200910198600.2, filed Nov. 10, 2009, commonly assigned, and incorporated by reference in its entirety for all purposes.

### BACKGROUND OF THE INVENTION

Embodiments of the present invention is directed to integrated circuits and their processing for the manufacture of semiconductor devices. More particularly, embodiments of the invention provide a semiconductor device having a 7F² memory cell structure. Embodiments of the present invention may be applied to a variety of semiconductor devices such as dynamic random access memory devices and others.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials.

Memory device scaling has been a challenging task. As an example, for non-volatile memory devices, the high density memory development is hindered by the inability to scale down the memory cell size without reducing the memory capacitance per unit area. Because memory device scaling is applied mostly to memory cells, array architecture often plays a crucial role in determining the chip size. Various memory cell structures have been developed. FIG. 1A depicts an example layout for an 8F2 cell. An 8F2 cell with a folded bit-line array configuration has been widely used in DRAM devices due to its improved signal to noise ratio. But an 8F2 cell may consume more cell area as compared to other cell configurations, such as a 6F2 cell as shown in FIG. 1B.

Although a 6F2 cell structure may provide some improvements in reducing cell size, some obstacles have arisen to adopting this technology for production. For example, in addition to some process challenges associated with smaller cells, a 6F2 cell structure uses an open bit-line configuration that is less immune to array noise, thereby degrading signal to noise ratio.

Accordingly, an improved memory cell structure for semiconductor memory devices is desired.

### SUMMARY OF THE INVENTION

Embodiments of the present invention provide a semiconductor device having a 7F2 cell structure, where F is the minimum feature size of the semiconductor device. In one embodiment, a bit line pitch of about 2\sqrt{3}F and a word line pitch of about 2F may be configured for the semiconductor device. In one embodiment, each of the active areas of the semiconductor device may be rotated around a corresponding center region to be offset from a corresponding bit line region. A plurality of imaginary equal lateral triangles may be formed by connecting center regions located on adjacent bit line regions and by connecting adjacent center regions located on the same bit line region. In this manner, the active areas for the semiconductor device can be arranged in a close compact pile mode within the cell plane, thereby achieving better cell area utilization.

Embodiments of the present invention may be applied to a variety of devices such as dynamic random access memory devices and others.

According to an embodiment of the present invention, a semiconductor device comprises a semiconductor substrate including a memory array region. The semiconductor device includes a plurality of bit line regions provided on one or more portions of the memory array region with each of the bit line regions being arranged in a continuous stripe manner from 1 through N, where N is an integer corresponding to a number of rows. A bit line pitch is configured to characterize the plurality of bit line regions. The semiconductor device includes a plurality of word line regions provided on one or more portions of the memory array region with each of the word line regions being arranged in a continuous stripe manner. The plurality of word line regions being arranged in an orthogonal manner relative to the plurality of the bit line regions to form an array configuration. A word line pitch is configured to characterize the plurality of word line regions. The semiconductor device includes a plurality of active area regions. Each active area region has a length and a width and corresponds to at least two memory cell regions. Each active area region also has a corresponding center region located on a corresponding bit line region. A plurality of imaginary equal lateral triangles may be formed by connecting the center regions located on adjacent bit line regions and by connecting adjacent center regions located on the same bit line region.

In one embodiment, the bit line pitch is about 1.7 times the word line pitch. In one embodiment, the bit line pitch is about 2\sqrt{3}F and the word line pitch is about 2F.

In one embodiment, each active area region is rotated about the corresponding center region to be off-set from the corresponding bit line region. In one embodiment, the off-set is 30 degrees counter-clockwise from the corresponding bit line region. In another embodiment, the off-set is 30 degrees clockwise from the corresponding bit line region. In this manner, the active area regions are in close compact pile mode, thereby achieving better cell area utilization for the semiconductor device.

In one embodiment, the semiconductor device includes one or more 7F² memory cells. In one embodiment, the semiconductor device is a dynamic random access memory (DRAM).

Various additional embodiments, features and advantages of the present invention can be more fully appreciated with reference to the detailed description and accompanying drawings that follow.

### BRIEF DESCRIPTION OF THE DRAWINGS

FIG. 1A is a simplified diagrams depicting an example layout for an 8F2 memory cell layout and FIG. 1B is a simplified diagrams depicting an example layout for a 6F2 memory cell;

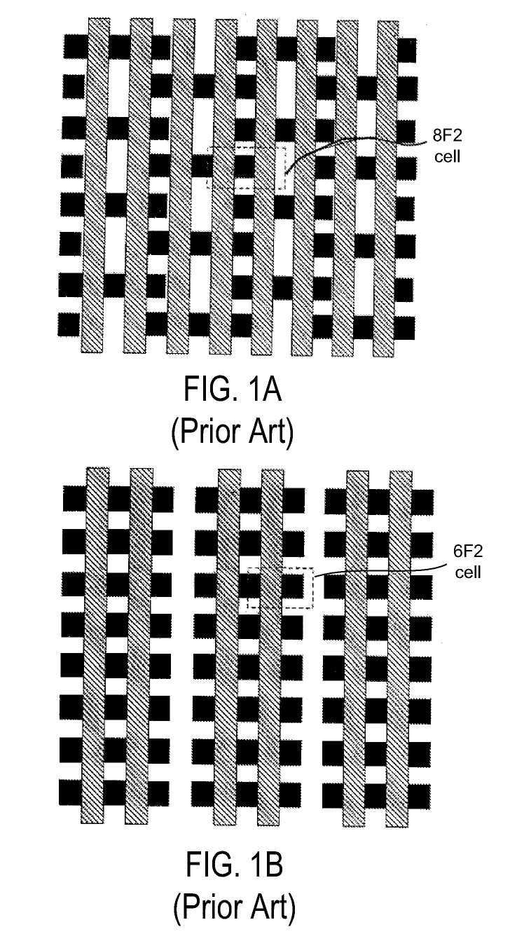

FIG. 2 is a simplified diagram depicting a semiconductor device having a 7F² cell structure according to an embodiment of the present invention;

FIG. 3 is a simplified diagram depicting a semiconductor device having a 7F² cell structure according to an embodiment of the present invention;

FIGS. 4A and 4B are simplified diagrams depicting semiconductor devices having a 7F² cell structure according to an embodiment of the present invention;

FIG. 5 is a simplified diagram depicting various geometric parameters of a 7F²-based semiconductor device according to an embodiment of the present invention;

FIGS. 6A-6C are simplified diagrams depicting various semiconductor devices having an 8F2 cell structure in the prior art.

### DETAILED DESCRIPTION OF THE INVENTION

In the following description, for the purposes of explanation, specific details are set forth in order to provide a thorough understanding of the invention. However, it will be apparent that the invention may be practiced without these specific details.

Embodiments of the present invention provide a semiconductor device having a 7F² cell structure. In one embodiment, a bit line pitch of about 2\sqrt{3}F and a word line pitch of about 2F may be configured for the semiconductor device. In one embodiment, each of the active areas of the semiconductor device may be rotated around a corresponding center region to be offset from a corresponding bit line region. A plurality of imaginary equal lateral triangles may be formed by connecting center regions located on adjacent bit line regions and by connecting adjacent center regions located on the same bit line region. In this manner, the active areas for the semiconductor device can be arranged in a close compact pile mode within the cell plane, thereby achieving better cell area utilization. In one embodiment, the semiconductor device is a dynamic random access memory (DRAM).

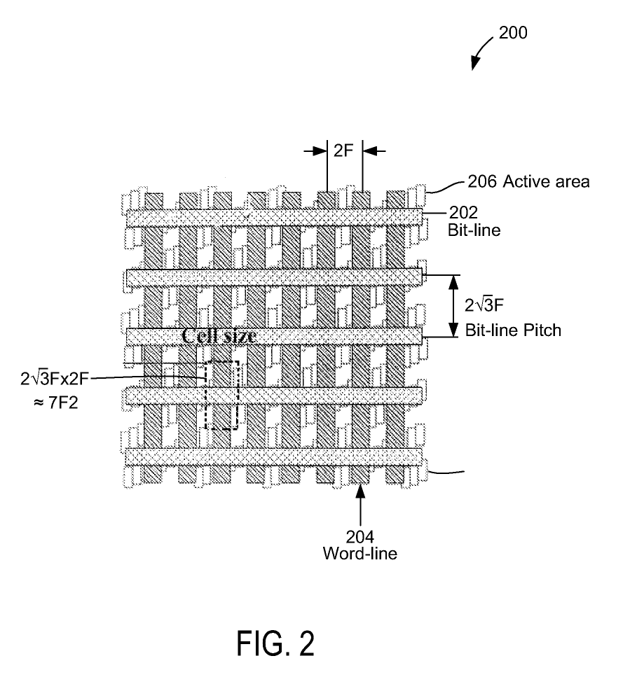

FIG. 2 is a simplified diagram depicting a semiconductor device 200 having a 7F² cell structure according to an embodiment of the present invention. As depicted in FIG. 2, semiconductor device 200 may include a plurality of bit lines 202. In one embodiment, the plurality of bit lines 202 is configured with a bit line pitch about 2\sqrt{3}F. Although FIG. 2 depicts only five bit lines 202, semiconductor device 200 may include any number of bit lines 202 arranged in a continuous strip manner from 1 to N, where N is an integer.

Semiconductor device 200 may also include a plurality of word lines 204 that are arranged in an orthogonal manner relative to the plurality of the bit lines 202 to form an array configuration. In one embodiment, the plurality of word lines 204 is configured with a word line pitch about 2F. Although FIG. 2 depicts only eight word lines 204, semiconductor device 200 may include any number of word lines 204 arranged in a continuous strip manner from 1 to N, where N is an integer.

The cell size for semiconductor device 200 may be determined based upon the bit line pitch and the word line pitch configured for the device. For example, the cell size for semiconductor device 200 may be calculated as the following, resulting in a 7F² memory cell structure:

Cell_Size=2\sqrt{3}F×2F=7F2

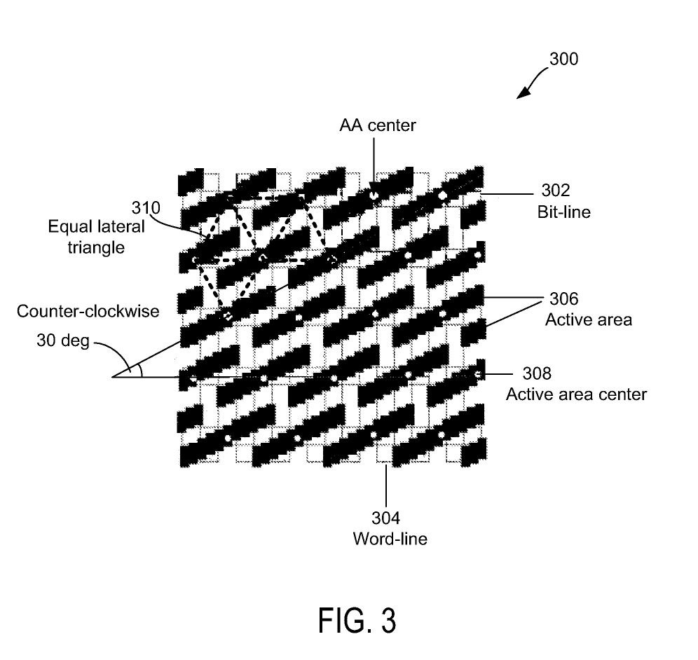

The bit-line width for bit lines 202 and the word-line width for word lines 204 may be determined according to specific process requirements. Semiconductor device 200 may further include a plurality of active areas 206, as will be described in more detail with reference to FIG. 3.

FIG. 3 is a simplified diagram depicting a semiconductor device 300 having a 7F² cell structure according to an embodiment of the present invention. Similar to semiconductor device 200 described above, semiconductor device 300 includes a plurality of bit lines 302, a plurality of word lines 304, and a plurality of active areas 306. As depicted in FIG. 3, each of the active areas for semiconductor device 300 may have an associated center region 308. In one embodiment, each center region 308 is located on at least one of the bit lines. In one embodiment, the distance between adjacent center regions 308 located on the same bit line may be configured to be about 4F.

In one embodiment, each active area 306 may be rotated around its corresponding center region 308 counter clockwise from the arrangement of bit lines 302. For example, as depicted in FIG. 3, the plurality of bit lines 302 are arranged horizontally. As such, active areas 306 may be rotated counter-clockwise around the corresponding center regions 308 from a horizontal direction. In one embodiment, each of active areas 306 may be rotated counter-clockwise around its corresponding center region 308 to be offset from the arrangement of bit lines 302 by 30 degrees. Such a configuration may result in a plurality of imaginary equal lateral triangles 310 when connecting center regions 308 located on adjacent bit lines 302 and by connecting adjacent center regions 308 located on the same bit line 302. In this manner, active areas 306 are arranged in a closer compact pile mode within the cell plane as compared to the configuration for an 8F2 cell structure, thereby achieving better cell area utilization for folded bit-line cells.

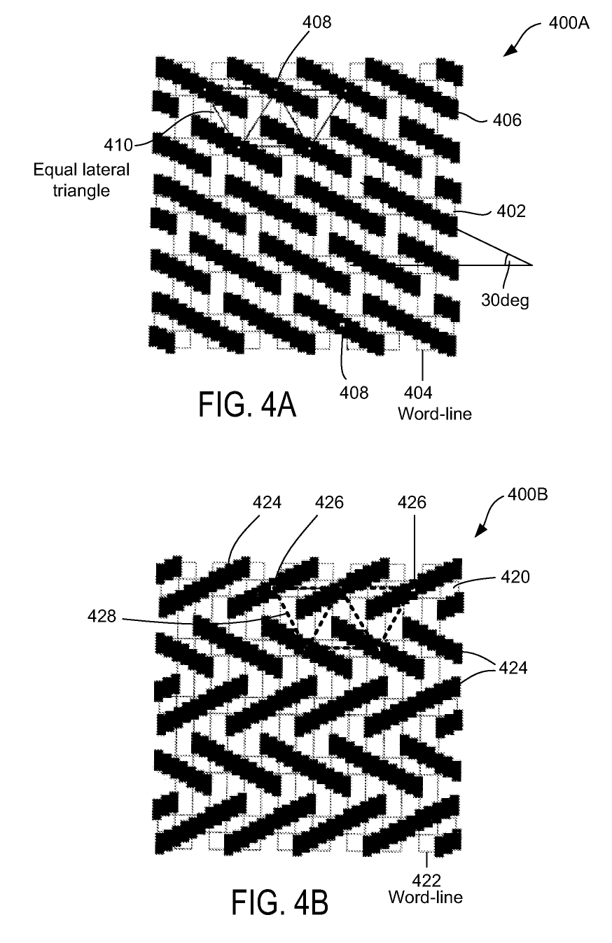

FIG. 4A and FIG. 4B are simplified diagrams depicting semiconductor devices (400A and 400B) having a 7F² cell structure according to an embodiment of the present invention.

As depicted in FIG. 4A, each of active areas 406 is rotated clockwise around its corresponding center region 408 to be offset from the arrangement of bit lines 402. In one embodiment, each active area 406 is rotated clockwise around its corresponding center region 408 to be offset from the arrangement of bit lines 402 by 30 degrees. A plurality of imaginary equal lateral triangles 410 may be formed by connecting center regions 408 located on adjacent bit lines 402 and by connecting adjacent center regions 408 located on the same bit line 402. In this manner, active areas 406 are in a closer compact pile mode within the cell plane as compared to the configuration for an 8F2 cell structure, thereby achieving better cell area utilization for folded bit-line cell structures.

FIG. 4B depicts a 7F² cell configuration for semiconductor device 400B in which active areas 424 are rotated interlaced between adjacent bit lines 420. For example, as depicted in FIG. 4B, if active areas 424 with corresponding center regions located on a first bit line 420 are rotated counter clockwise from the arrangement of the first bit line, then active areas 424 with corresponding center regions 426 located on an adjacent bit line 420 are then rotated clockwise from the arrangement of the adjacent bit line. A plurality of imaginary equal lateral triangles 428 may be formed by connecting center regions 426 located on adjacent bit lines 420 and by connecting adjacent center regions 426 located on the same bit line 420. In this manner, active areas 424 are in a closer compact pile mode within the cell plane as compared to the configuration for an 8F2 cell structure, thereby achieving better cell area utilization for folded bit-line cell structures.

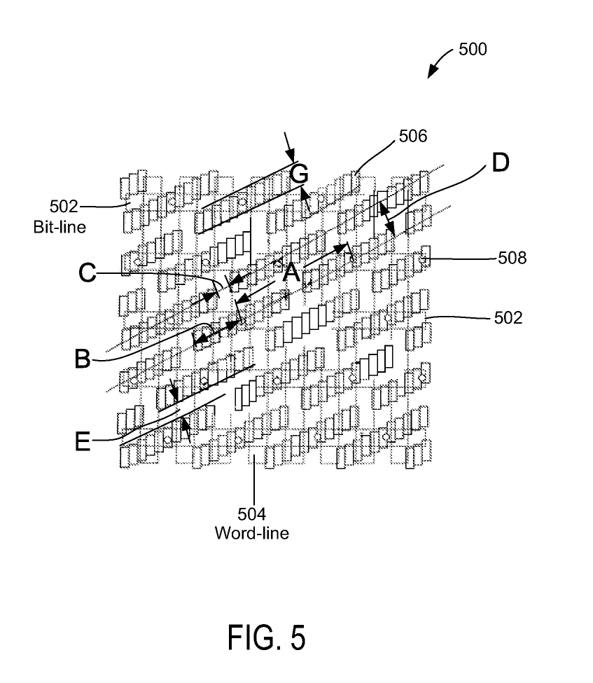

FIG. 5 is a simplified diagram depicting various geometric parameters for a 7F²-based semiconductor device 500 according to an embodiment of the present invention. As depicted in FIG. 5, “A” denotes an active area pitch that measures the distance between center regions 508 for adjacent active areas 506 located on the same line. In one embodiment, “A” may be about 4\sqrt{3}F. “B” denotes a half length for each active area 506. In one embodiment, “B” may be about (5\sqrt{3}/3)F. “C” denotes a distance between adjacent active areas 506 located on the same line that is offset relative to the bit line by a rotation. In embodiment, “C may be about (2\sqrt{3}/3)F. “D” denotes an active area pitch that measures the distance between center regions 508 for active areas 506 located on adjacent bit lines 502. In one embodiment, “D” may be about 2F. “E” denotes a distance between active areas 506 located on adjacent bit lines 502. In one embodiment, “E” may be about F. “G” denotes a width for each active area 506. In one embodiment, “G” may be about F.

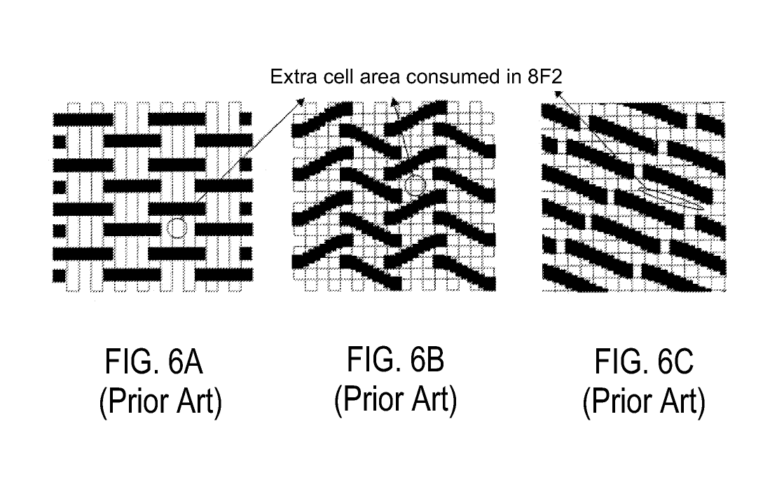

FIGS. 6A-6C are simplified diagrams depicting various semiconductor devices having an 8F2 cell structure. As depicted in FIGS. 6A-6C, active areas for these semiconductor devices are arranged in a less compact manner when compared to the various 7F² configurations described above. As such, embodiments of the present invention achieves better cell area utilization as compared to an 8F2 cell structure.

The 7F²-based memory cell structure described above for a semiconductor device achieves better cell area utilization for folded bit-line cell structures as compared to 8F2-based cells. In one embodiment, a bit line pitch of about 2\sqrt{3}F and a word line pitch of about 2F may be configured for the semiconductor device having a 7F² cell structure. In one embodiment, active areas for the semiconductor device may be rotated counter-clockwise or clockwise around a corresponding center region to be offset from the arrangement of bit lines. A plurality of imaginary equal lateral triangles may be formed by connecting center regions located on adjacent bit lines and by connecting adjacent centers located on the same bit line. In this manner, active areas for the semiconductor device can be arranged in a close compact pile mode within the cell plane. Such a configuration eliminates the extra areas that are consumed in an 8F2 cell, thereby reducing the overall cell size for the semiconductor device.

While the embodiments and advantages of the present invention have been depicted and described, it will be understood by those skilled in the art that many changes in construction and differing embodiments and applications of the invention will suggest themselves without departing from the spirit and scope of the invention. Thus, the disclosures and descriptions herein are purely illustrative and are not intended to be in any sense limiting.

What is claimed is:

1. A semiconductor device comprising:
a semiconductor substrate comprising a memory array region;
a plurality of bit line regions provided on one or more portions of the memory array region, each of the bit line regions being arranged in a continuous stripe manner from 1 through N, where N is an integer corresponding to a number of rows;
a bit line pitch characterizing the plurality of bit line regions;
a plurality of word line regions provided on one or more portions of the memory array region, each of the word line regions being arranged in a continuous stripe manner, the plurality of word line regions being arranged in an orthogonal manner relative to the plurality of the bit line regions to form an array configuration;
a word line pitch characterizing the plurality of word line regions;
a plurality of active area regions, each active area region having a length and a width, each active area region corresponding to at least two memory cell regions, each active area region having a corresponding center region located on a corresponding bit line region; and
a plurality of imaginary equal lateral triangles formed by connecting the center regions located on adjacent bit line regions and by connecting adjacent center regions located on the same bit line region.

2. The semiconductor device of claim 1, wherein the bit line pitch is about 1.7 times the word line pitch.

3. The semiconductor device of claim 1, wherein each active area region is rotated about the corresponding center region to be off-set from the corresponding bit line region.

4. The semiconductor device of claim 3, wherein the off-set is 30 degrees counter-clockwise from the corresponding bit line region.

5. The semiconductor device of claim 3, wherein the off-set is 30 degrees clockwise from the corresponding bit line region.

6. The semiconductor device of claim 1, wherein the bit line pitch is about 2\sqrt{3}F.

7. The semiconductor device of claim 1, wherein the word line pitch is about 2F.

8. The semiconductor device of claim 1, wherein the semiconductor device includes one or more 7F² memory cells.

9. The semiconductor device of claim 1, wherein the semiconductor device is a dynamic random access memory (DRAM).

10. The semiconductor device of claim 1, wherein the active area regions are in close compact pile mode, thereby achieving better cell area utilization for the semiconductor device.
